(19) United States
(12) Patent Application Publication
(10) Pub. No.: US 2007/0025494 A1
(43) Pub. Date: Feb. 1, 2007

(54) Neutrino telescope

(76) Inventor: Robert W. Beckwith, Clearwater, FL (US)

Correspondence Address: Leo J. Aubel, 111 Rivershire Lane, Lincolnshire, IL, 60069, US

(21) Appl. No.: 11/410,356

(22) Filed: Apr. 25, 2006

Related U.S. Application Data
(60) Provisional application No. 60/687,494, filed on Jun. 3, 2005.

(51) Int. Cl. G01T 3/00; G21G 1/00; H01L 41/00

(52) U.S. Cl. 376/153; 376/156; 455/899; 310/311

(57) ABSTRACT

A neutrino telescope is made up of four devices. A neutrino modulating device velocity modulates neutrinos passing through a thin walled steel tube. This encodes the neutrinos as being different than any neutrinos found in nature. The steel tube is electrically driven to its lengthwise resonant frequency. A directive steel tube can be added, as a second device, to restrict neutrinos passing into the telescope and the directional resolution thus improved. A third device uses a barium titanate cylinder to detect forces from modulated neutrinos. An analog circuit filters and amplifies the signal as necessary. An oscilloscope can be used to measure and study the output. A fourth device uses a Blackfin processor to provide digital processing and a service computer for further processing and studying results over periods of time.

This application claims the date of Provisional Patent Application 60/687,494 filed Jun. 3, 2005. Please note the change in title.

### A NEW LAW OF NATURE

This patent application is based on the following new law of nature:

### A FORCE MODEL OF THE UNIVERSE AND THE ROLE OF NEUTRINOS

This paper is included in its entirety in reference patent U.S. Pat. No. 6,891,310 B2.

### REFERENCES

1. U.S. Pat. No. 6,891,310, A NEUTRINO LIGHT TO PHOTON LIGHT CONVERTING MATRIX, issued to Robert W. Beckwith, the present inventor, on May 10, 2005
2. A FORCE MODEL OF THE UNIVERSE AND THE ROLE OF NEUTRINOS, a paper by the present inventor included herein by reference. This paper gives new theories of nature and about neutrinos in particular. Neutrinos are packets of electromagnetic waves driven by their force along force lines. All of the universe has a flux of force lines connecting all objects having mass. Force lines are tubes the size of electrons. All nuclear reactions produce neutrinos including the Sun, the center of the Earth and an unknown number of heavenly bodies. The present invention relies on these new theories, especially the theory that neutrinos have force but not mass. This book is available for downloading at no cost from www.beckwithelectric.com

### SUMMARY

A neutrino telescope (NT) consists of combinations of four devices, some having more than one form, as follows:

In a first neutrino modulator device, Beckwith Electric Company (BECO) M-7001, a thin walled steel tube is made to vibrate at the lengthwise resonant frequency of the tube by placing a winding of wire on a plastic tube and driving the winding with an oscillator at the lengthwise resonant frequency of the tube. The magnetic path lengthwise through the thin walled tube is continued through a thick walled steel tube outside of the winding. The magnetic path is further continued across each end of the telescope through steel caps and across radial air gaps to each end of the thin walled steel tube. A carefully selected space between the outside of the thin walled steel tube and the inside of said plastic tube permits the steel tube to easily vibrate lengthwise with little mechanical resistance from the plastic tube. All steel parts are treated with a finish so as not to rust.

The magnetic path around the outside of the winding is much thicker than the thickness of said thin walled steel tube permitting current in the winding to drive most of its energy into the tube causing the tube to vibrate longitudinally.

The thin walled steel tube is restrained lengthwise at each end by rubber O rings in a plastic cap extending beyond the steel end caps. Removing the first O ring permits easy removal of the thin walled steel tube for cleaning or replacing when necessary.

The oscillating circuit is selectively powered by high energy rechargeable batteries or by other sources as convenient.

Neutrinos are modulated in speed as they pass through the longitudinally vibrating magnetic field inside of the thin walled steel tube. Thus they are modulated in force in accordance with theories advanced by the present inventor.

In a second device, the BECO model M-7002, a receiver for the neutrino modulated frequency consists of a 1″ diameter disc of barium titanate material. A block of this material was used as a receiver in the first experimental apparatus. A problem existed in pickup of fluorescent light ballast signals, an AM broadcast station and other unknown signals. A bandpass filter is used in one embodiment of the second device in the current invention to eliminate these signals.

A second embodiment of the second device is the BECO model M-7003. Here the output of the barium titanate disc is processed by a Blackfin processor and then transmitted by a wireless BlueTooth circuit to a Lenovo Thinkpad service computer equipped for BlueTooth communications. The Blackfin processor and its program does the bandpass filtering, and further greatly increases the dynamic range of the NT. Customized programs in the service computer process and display the received information from the neutrino telescope.

A third device is a BECO M-7004 oscillator driver for the M-7001 neutrino modulator unit.

A fourth optional device, the BECO M-7005 for giving the NT greater directional resolution, is available. This adds a steel tube ahead of the neutrino modulator device for giving the NT greater directional resolution.

A brief description of figures useful in describing the inventive devices and circuits:

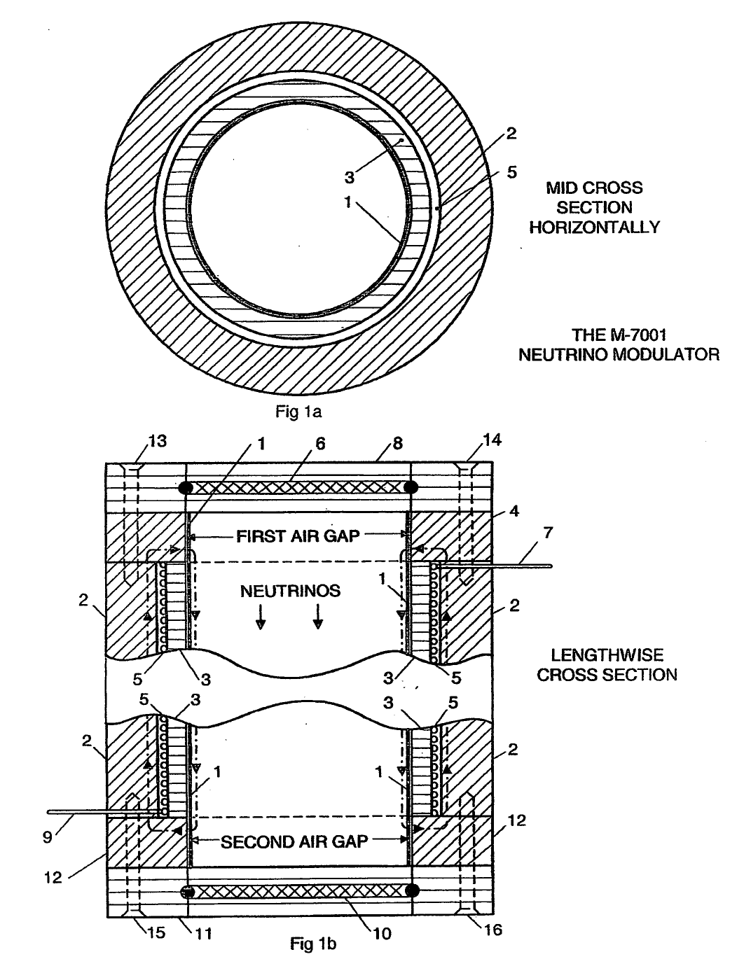

FIG. 1a A mid cross section of the neutrino modulator device.

FIG. 1b A lengthwise cross section of the neutrino modulator device.

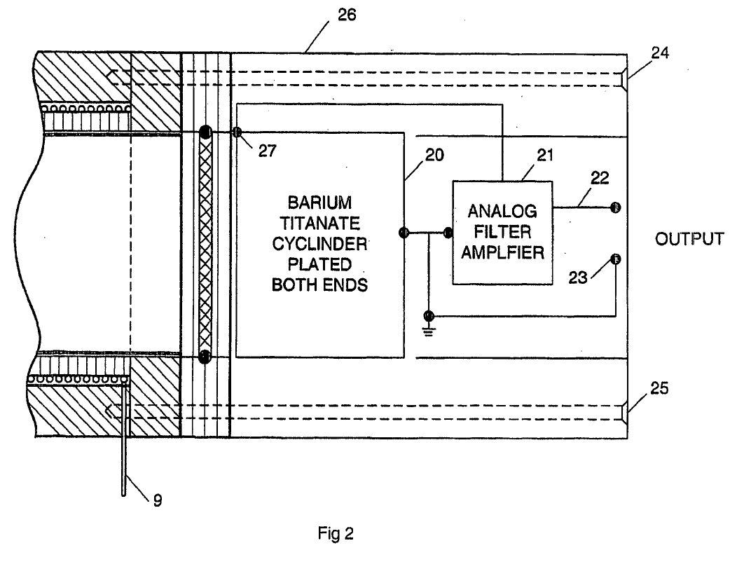

FIG. 2 A diagram of the barium titanate disc neutrino force receiver device using an analog bandpass filter and amplifier.

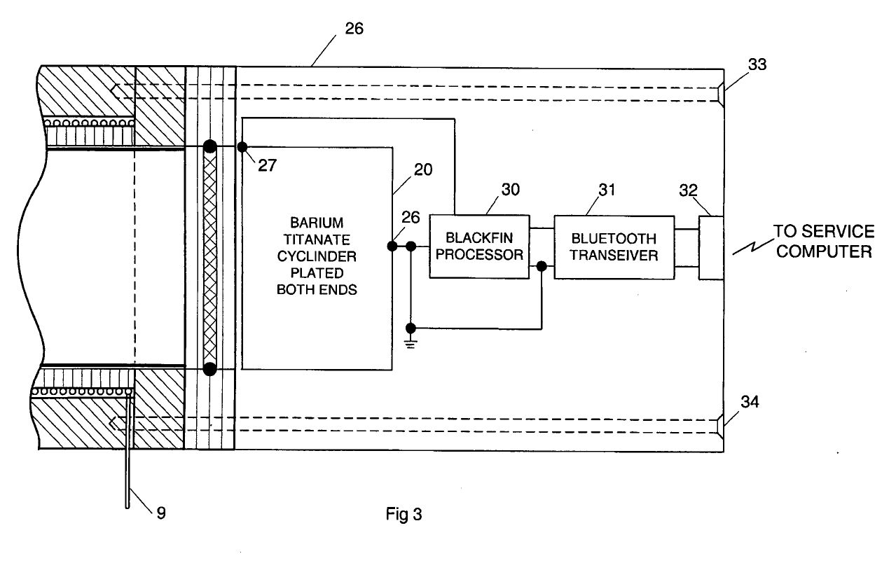

FIG. 3 A diagram of the barium titanate disc neutrino force receiver device using a Blackfin processor providing a digital bandpass filter and enhancing the dynamic range of the NT.

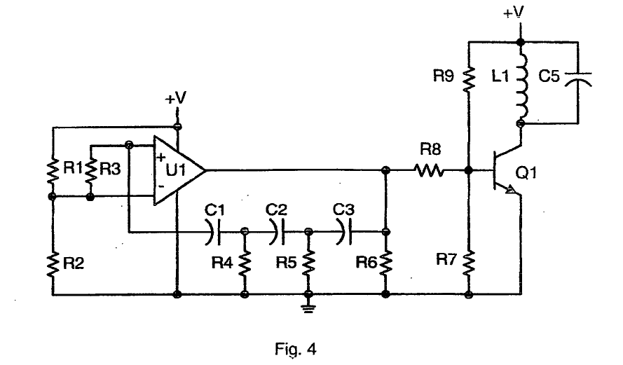

FIG. 4 An oscillator and driver device circuit diagram for the neutrino modulator device winding.

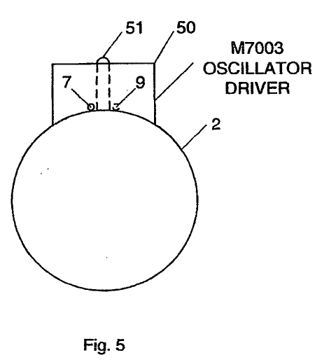

FIG. 5 A depiction of the mounting of a box containing the oscillator and driver device.

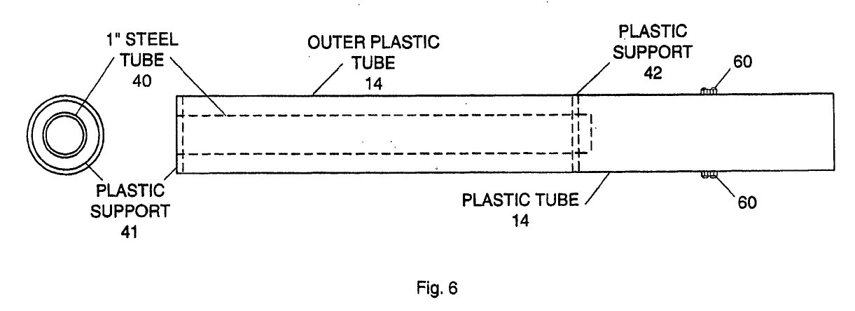

FIG. 6 An optional steel tube device for giving the NT greater directional resolution.

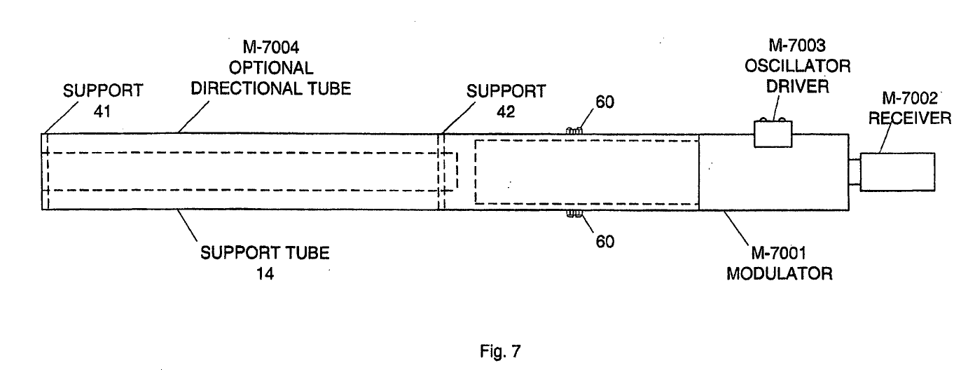

FIG. 7. An assembly of the four devices to form an neutrino telescope (NT).

### SUMMARY OF RESULTS OBTAINED WITH APPARATUS DESCRIBED IN THE PROVISIONAL PATENT APPLICATION

As a result of partial failure to make the structure of the provisional patent application detect neutrinos, a number of interesting things about neutrinos were discovered:

1. Neutrinos will not pass through steel! In fact they pass through all solid materials with some amount of difficulty. Note that they surely do not pass through the center of the Earth or penetrate any large part of the Earths' crust.

2. Steel (and likely many other materials) can be used to form a “wave guide” for neutrinos. The first structure detected neutrinos flowing through the space between a steel bar and a steel tube used as an outer shield for a winding driving both at their lengthwise resonant frequency. The bar and the outer shield vibrated lengthwise yielding an ill defined wave guide for velocity encoding neutrinos. Nevertheless data gathered supported the possibility of constructing a neutrino telescope and led to the present utility patent application.

3. Neutrinos can be velocity modulated by varying magnetic fields and the modulation detected by material such as barium titanate which responds to varying force. This implies that velocity modulation is equivalent to force modulation and is supported by the present inventors reference paper that neutrinos have force but not mass.

The barium titanate piece terminated with electrical connections to a battery operated oscilloscope did detect neutrino flow from the Sun and from the center of the Earth. However it also picked up much interfering electromagnetic waves such as from fluorescent light ballasts, from radio broadcast stations and from 60 Hz power equipment.

We felt that the basic principle for a neutrino telescope had been established. A receiver responsive only to a frequency band around the telescope excitation frequency seemed necessary.

The barium titanate mixture K700 was supplied by Keramos Advanced Piezoelectrics, a division of Piezotechnologies located in Indianapolis Ind.

These findings lead to the use of a mechanically vibrating thin walled steel tube for producing unique velocity modulation of neutrinos passing through the tube. There is no reason to expect such modulation will be found in nature, especially with selected rates of modulation matching varying lengths of the tube.

### Description of the Inventive Devices and Combinations of Devices

As an alternative approach to the difficult task of miniturizing elements of the matrix of the reference #1 patent, a serial approach is taken in the present invention. Neutrinos are velocity modulated at a lengthwise resonant frequency of a thin walled steel tube through which neutrinos flow. This has resulted in a Neutrino Telescope (NT) capable of being scanned mechanically over an area of interest and creating the conversion of neutrino light into photon light for human viewing in a service computer.

The neutrino telescope consists of combinations of devices, some of which have more than one form.

1. A BECO M-7001 neutrino modulator device for velocity modulating a stream of neutrinos thus encodding those neutrinos as different from neutrinos found in nature.

2. A first BECO M-7002 receiver device using a barium titanate ceramic disc for receiving the neutrino force modulation resulting from the velocity modulation. This device uses an analog bandpass filter/amplifier to filter out unwanted signals picked up by the disc. The device also amplifies signals as required in viewing neutrino sources of varying brightness. It is anticipated that this device may make possible the viewing of some planets of the solar system. This receiver will be developed first since little programming is required to make it function.

3. A second alternate BECO M-7003 receiver unit using a barium titanate ceramic disc for receiving the neutrino force modulation resulting from the velocity modulation. This unit uses a Blackfin processor with digital bandpass filter and programs for greatly extending the dynamic range of the NT. Ultimately this device may make possible the viewing of nearby stars. This receiver includes a BlueTooth transceiver for interfacing with a Linovo Thinkpad user computer. Considerable programming is required, first for the Blackfin processor and secondly for the user computer.

4. A BECO M-7004 oscillator/driver device for driving a winding in the M-7001 device to cause a very thin walled steel tube to vibrate mechanically at its lengthwise resonant frequency.

Note that the combination of an M-7001 neutrino modulator device with either the M-7002 or M-7003 neutrino force receiver device forms a Neutrino Telescope (NT).

5. A BECO M-7005 steel tube assembly selectively used to improve the directional resolution of the NT.

FIG. 1a shows a mid cross section of an M-7001 neutrino modulator device. FIG. 1b shows a lengthwise cross section. Thin walled steel tube 1 forms a wave guide through which neutrinos can pass. Magnetic fields are created by winding 5 wound on plastic tube 3.

IEEE Dictionary 100 of IEEE Standard Terms defines “magnetomotive force (acting in any closed path in a magnetic field) The line integral of the magnetizing force around the path” (Std100) 270-1966w

It is known that magnetomotive force lines always flow in loops having neither beginning nor end. In such a loop a cylindrical pattern of oscillating magnetomotive force lines flows upward through thick walled steel tube 2 to an end of said tube 2. In an upper end of said neutrino modulator unit, as seen in FIG. 1b, magnetomotive force lines flow radially inward through steel end cap 4, across a first air gap, and to the upper end of tube 1. Magnetomotive force lines from the lower end of tube 1 flow radially outward across a second air gap to steel end cap 12 and to the lower end of thick walled steel tube 2, thus completing the magnetomotive force line loop.

The space between winding 5 and the inside of steel tube 2 is supported in a way that produces a very close fit between the inside of plastic tube 3 and tube 1. Thus the very light weight tube 1 is the only part of the neutrino modulator unit 1 that is free to move relative to the much greater mass of the rest of the modulator.

The assembly of steel tube 2 and end caps 4 and 12 is held in alignment by precision screws 13, 14, 15, and 16. Four additional screws, not shown, complete the function with four screws used at either end of the neutrino modulator device.

FIGS. 1a and 1b do not show the mounting of modulated neutrino receiver of either FIG. 2 or 3. As shown the model M-7001 device is useable only with hand held modulated neutrino receiver devices.

The light weight, 0.108 pounds, of tube 1 reduces the energy required to cause the tube 1 to vibrate at its lengthwise resonant frequency.

While in theory the vibration of the tube 1 will change the magnetomotive force line field, the line integral of the magnetizing force from end to end of tube 2 and through end caps 4 and 12 is very high in comparison to the line integral of the magnetizing force through tube 1. Therefore the oscillating electric current in winding 5 induced into tube 1 creates a lengthwise mechanically vibrating magnetic field within tube 1 which is virtually unchanged by the lengthwise vibration. Neutrinos flowing through tube 1 therefore react to the magnetic field within the tube. They travel at nearly the theoretical speed of light relative to the immediate magnetic field.

Thus when tube 1 and its magnetic field is moving with the flow of neutrinos the neutrinos will travel at nearly the theoretical speed of light plus the velocity of tube 1 and its magnetomotive force. When tube 1 and its magnetic field are moving against the flow of neutrinos the neutrinos will travel at nearly the theoretical speed of light less the velocity of tube 1 and its magnetomotive force. The vibrating motion of tube 1 thereby adds an identifying vibrating velocity (force) encoding to the neutrinos passing through tube 1 by which the neutrinos can be recognized by a neutrino force reactive receiver such as described in either FIG. 2 or 3. In light of the law of nature cited above, I claim that neutrinos are electromagnetic waves and have forces active at any velocity dependent on their immediate magnetomotive force environment.

When winding 5 is energized by an AC current flowing via terminals 7 and 9, magnetomotive forces keep tube 1 centered lengthwise within the neutrino modulator unit. Rubber O rings 6 in plastic end cap 8 and rubber O ring 10 in plastic end cap 11 keep the tube 1 from falling out when winding 5 is not energized.

All steel parts are treated to prevent rusting.

Thin walled steel tube 1 fits snugly into plastic tube 3. Delrin is the preferred plastic for all plastic parts of this invention since it does not absorb moisture and is slippery related to steel. Plastic tube 3 may be milled out to obtain the snug fit desired. Furthermore both plastic tube 3 and steel tube 1 are polished to provide a slippery fit.

FIGS. 1a and 1b show a neutrino modulator with no attached receiver as shown below in FIGS. 2 and 3. Experiments can be made with a hand held receiver to find the spreading pattern of neutrinos as they come from a restricted tube into the open atmosphere.

FIG. 2 shows a BECO model M-7002 modulated neutrino receiver device. This model uses an analog bandpass filter to pass a band of frequencies with 4220 Hz as the center for a 12″ long resonant tube. Sufficient amplification is included to measure neutrinos from large planets such as Saturn or Venus. It is expected that the output will be connected to an oscilloscope for manual viewing. This has the advantage of not requiring processor programming thus reducing the product development time.

The forces from the neutrino modulation are received by a one inch diameter barium titanate cylinder 20 cut from the slab used in the first experimental which did show that the material does respond to the neutrino modulation. Two cylinder were cut from the original slab which is known to react to modulated neutrinos. The depth of penetration of neutrinos into this material is not known. An experiment will be conducted with the first two cylindrical disks in order to determine the depth of penetration.

One disc will be installed in the M-7002 prototype device and the telescope pointed at the Sun. A maximum reading will be obtained on an oscilloscope used to measure the output of the filtered and amplified signal. The second disc will be hand held across the input of the telescope and the output noted on the oscilloscope. From this the depth of penetration can be calculated.

Should the signal not be seen by the oscilloscope, it is known that the depth of penetration is much greater than the disc thickness of about ⅞″. The handheld disc will be sent to the manufacturer for slicing into thinner pieces. The experiment will be repeated.

Since the receiver barium titanate disc is the most expensive part in the telescope, it will reduce the cost to use an optimum thickness of disc.

The barium titanate cylinder (disc) 20 is plated on both ends and wires attached. A ground wire from surface 20 is attached to the ground of analog filter/amplifier 21. A wire from surface 27 is connected to analog filter/amplifier 21 for filtering and amplifying signals from surface 27.

A filtered and amplified output consists of ground reference 23 and filter/amplifier output 22.

FIG. 3 shows a BECO model M-7003 modulated neutrino receiver device. This device uses a barium titanate cylinder 20 to receive forces from modulated neutrinos as did the device of FIG. 2. The cylinder of FIG. 3 may be of more optimum length depending on experiments with a FIG. 2 device.

Plated terminal connections 26 for ground and 27 for active input are connected to Blackfin processor 30. Programs in processor 30 form a virtual bandpass filter to eliminate undesired signal pickup by cylinder 20. Computations are done in floating point mathematics. The output is four decimal digits for the size of a target on Earth, a planet or a star. The decimal point will be at least 10 decimal digits, computed to be necessary to see the nearest star system, Sirius. It will be interesting to find whether device noise, intergalactic noise or other noise will make the distant viewing possible. In any event, experiments with model M-7003 devices should point the way for further research.

Beckwith Electric Company has experience with the rather remarkable Blackfin processor, however the program writing time for this application will be considerable.

FIG. 4 shows the circuit of a BECO model M-7004 device. This combination of an oscillator followed by a current driver is used to cause current to flow through inductance L1 (winding 5) of the neutrino modulator device. Note that the tight coupling of the magnetic path means that the inductive impedance to be driven is quite high. The inductance L1 is therefore resonated by capacitor C5.

A phase shift oscillator is formed by operational amplifier U1 and three 60° phase shift circuits: C1/R4, C2/R5, and C3/R6. Thus the feedback from U1 output to U1 (+) input is 180°. R1 and R3 place a dc reference voltage on U1 (−) input. Resistor R3 puts the same reference voltage on U1 (+) as on U1 (−).

U1 is chosen for a high gain bandwidth ratio causing the circuit to oscillate properly at the 12″ long tube 1 lengthwise resonant frequency of 4220 Hz.

The output of the U1 oscillator as seen across resistor R6 is a square wave. Resistors R7, R8 and R9 therefore drive the input to transistor Q1 with a square wave. A square wave current through inductance L1 would produce a square wave modulation of neutrinos traveling through tube 1. This seems desirable and use of capacitor C5 will be determined in the future.

FIG. 5 shows a box 50 for housing the M-7004 device. Said box is mounted along tube 2 in a location otherwise vacant. Wires 7 and 9 are shown on FIG. 1b. The wires pass through slots in ends of tube 2 and are located radially to convenience entering box 50.

Box 50 is fastened to tube 2 by two screws 51 located one behind the other at opposite ends of box 50.

FIG. 6 shows the BECO M-7005 unit. This unit can be added if desired to improve the forward looking resolution, such as possibly seeing solar flares as distinguished from the rest of the Sun. Steel tube 40 is supported inside of plastic tube 43 by plastic supports 41 and 42. Screws 60 can be used to prevent the tube from slipping when used on a telescope.

FIG. 7 shows an assembly of optional M-7005 unit placed on an M-7001 modulator, powered by a M-7004 oscillator/driver with the modulated neutrino signal picked up with an M-7002 or M-7003 receiver. Screws 60 are tightened as required to keep the M-7004 device from sliding off.

This combination of devices becomes a Neutrino Telescope.

### ADVANTAGES OF THE INVENTION

1. With the telescope looking at the sun, various thicknesses of steel plates can be placed across the viewing end of the telescope and the reduction in received signal noted. This will give the depth of penetration into steel for neutrinos. This can be repeated for many other materials. Perhaps the reduction will be non-linear. The material may act as a filter for various neutrino strengths and colors.

2. Look at the Sun on cloudy days. Does the neutrino strength change when clouds go past the Sun? What happens during severe storms and hurricanes?

3. With the directive tube assembly added, can sunspots be resolved from the rest of the Sun? Is the neutrino output from sunspots greater than the average Sun as a whole?

4. What happens when the Sun goes down at evening or rises in the morning? How far below the horizon can the Sun be seen?

5. A study of neutrinos from the Earths' core should be interesting. Geologists should be interested in the variation of Earth neutrinos as a function of the angle the telescope looks down as well as the variations from various points on the Earths' surface.

1. A neutrino telescope device comprising in combination,
a) a lightweight tube means for forming a waveguide for neutrinos,
b) said tube means having very small depth of neutrino penetration,
c) said tube means having properties responsive to magnetizing forces,
d) slippery mounting means for permitting said tube to move freely,
e) magnetomotive force source modulation means for causing said tube to vibrate mechanically at its lengthwise resonant frequency, and
f) magnetomotive force source means for producing a magnetic field that moves with said tube,
thereby encoding neutrinos received by said tube waveguide with the frequency of the lengthwise mechanical resonance of said tube.

2. A neutrino telescope device as in claim 1 further comprising in combination,
a) barium titanate means for detecting said encoding frequency,
b) a service computer means having a display screen,
c) signal processing means for processing said detections of encoding frequencies and preparing for sending to said service computer, and
d) service computer program means for receiving processed information from encoded neutrinos and further processing and displaying on said service computer screen.

3. A neutrino modulation device comprising the following in combination,
a) thin walled steel tube means for velocity modulating neutrinos passing through said thin walled steel tube,
b) plastic tube means for holding said thin walled steel tube with minimal room for said thin walled steel tube to vibrate lengthwise within said plastic tube,
c) plastic tube wire winding means for carrying current to produce a magnetic field within said thin walled steel tube,
d) thick walled steel tube means for returning said magnetic field,
e) a first steel end cap means for carrying said magnetic field from a first end of said thick walled steel tube to an air gap and to the field at the first end of said thin walled steel tube,
f) a second steel end cap means for carrying said magnetic field from a second end of said thin walled steel tubing to an air gap at the second end of said thick walled steel tubing, and
g) means for providing frequency control of said current means for causing said thin walled steel tube to vibrate and velocity modulate neutrinos flowing through said tube.

4. A device as in claim 3 further comprising in combination:
a) barium titanate bar means for receiving forces from velocity modulated neutrinos,
b) analog band pass filter means for rejecting undesired signals picked up by said barium titanate bar.
c) amplifying means for amplifying desired signals picked up by said barium titanate bar, and
d) instrumentation means for viewing desired signals picked up by said barium titanate bar
thereby forming a neutrino telescope.

5. A device as in claim 3 further comprising in combination:
a) barium titanate bar means for receiving forces from velocity modulated neutrinos,
b) digital means for separating desired signals from undesired signals picked up by said barium titanate bar,
c) floating point programming means for said digital means for providing wide dynamic range for signals picked up by said barium titanate bar,
d) display means for displaying magnitude and decimal point information about signals picked up by said barium titanate bar thereby forming a neutrino telescope.

6. A device as in claim 5 further including the wireless exchanging of information about signals picked up by said barium titanate bar with a service computer means for further processing and data storage.

7. A method of making a neutrino telescope, the method comprising the steps of:
a) receiving neutrinos in a wave guide,
b) vibrating said wave guide at its longitudinal resonant frequency,
c) provide a vibrating magnetomotive force that moves with the wave guide as it vibrates,
d) transfer the vibrations of said wave guide to vibrations of neutrino forces as they move through said wave guide,
e) receive the vibrating force of the neutrinos as an electrical signal,
f) process said electrical signal as desired by users of said neutrino telescope.
